(19) United States
(12) Patent Application Publication
(10) Pub. No.: US 2003/0042969 A1
(43) Pub. Date: Mar. 6, 2003

(54) Current Mirror circuit

(75) Inventors: Alex Yu-Kwen Su, Hsin-Chuang City (TW); Yen Chang Tung, Guei-Ren Village (TW)

Correspondence Address: BACON & THOMAS, PLLC, 625 SLATERS LANE, FOURTH FLOOR, ALEXANDRIA, VA, 22314

(73) Assignee: Media Scope Technologies Corp, Taipei County (TW)

(21) Appl. No.: 09/945,837

(22) Filed: Sep. 5, 2001

(51) Int. Cl. H01L 29/76

(52) U.S. Cl. 327/538

(57) ABSTRACT

The present invention provides an improved current mirror circuit. For example, in a voltage controlled oscillator of a phased-locked loop circuit, MOS device is used to replace a fixed resistor in the control circuit before the current mirror circuit for controlling the mirror currents of the related MOS devices in the phased-locked loop circuit, and for controlling the operating frequency of the phased-locked loop circuit.

### FIELD OF THE INVENTION

The present invention relates to an improvement of a current mirror circuit, and more particularly to an improved current mirror circuit in a phase-locked loop circuit for improving the controllability and accuracy thereof.

### BACKGROUND OF THE INVENTION

A conventional phase-locked loop circuit is shown in FIG. 1, in which a signal fin of some frequency is inputted into a divider 11 for being frequency divided by M to become a signal fin/M, and then inputted into a phase frequency detector 12.

The phase frequency detector 12 will be inputted with another feedback signal fr having the same frequency with fin/M. The signal fr is a modified reference signal for adjusting the phase of fin/M. If the phase of fin/M is ahead of fr, then the phase frequency detector 12 will generate an UP signal. If the phase of fin/M falls behind fr, then the phase frequency detector 12 will generate a DN signal.

The UP signal or the DN signal will be inputted into a charge pump circuit 13 for generating a corresponding voltage Vctrl to be inputted into a low pass filter 14.

The output Vo of the low pass filter 14 will be inputted into a voltage controlled oscillator 15 for generating an oscillating signal to be inputted into a prescaler circuit 16. After processed by the prescaler circuit 16, an oscillating signal fo will be inputted into a divider 17 for generating a required accurate frequency.

The signal fo is also inputted into another divider 18 for being frequency divided by N to generate the signal fr, and then inputted into the phase frequency detector 12. The frequency of fr is the same as that of fin/M.

Referring to FIG. 2, which shows an improved voltage-controlled oscillator in a phase-locked loop circuit. The ouput voltage Vo of the low pass filter 14 in the phase-locked loop circuit is inputted into the gate of an NMOS MN1. One terminal of the MN1 is connected with a resistor R1 to the ground, another terminal of the MN1 is connected with a PMOS MP1 to the Vcc. The gate of MP1 is connected with the connection between MP1 and MN1, as shown in the figure, thus a signal VM is generated at the gate of MP1.

VM is a voltage signal and will be inputted into the gate of each PMOS MP2, MP3, MP4, MP5 and MP6 in the voltage-controlled oscillator. One terminal of each PMOS MP2, MP3, MP4, MP5 and MP6 is connected with Vcc, while another terminal is connected with the control terminal of inverters 21, 22, 23, 24, 25 respectively. Inverters 21, 22, 23, 24, 25 are connected serially to form a ring, as shown in the figure. The output of MP6 is inputted into an amplifier 26, and the output of the amplifier 26 is inputted into a multiplexor 27. Another input terminal of the multiplexor 27 can be inputted with a votage transferred from a digital data DATA by a digital-to-anolog converter 28. The multiplexor 27 has two switches S1 and S2 for selecting the output of either the amplifier 26 or the digital-to-anolog converter 28 as the CC1 signal to be inputted simultaneously into the gate of each PMOS MP7, MP8, MP9, MP10, and MP11. One terminal of each MP7, MP8, MP9, MP10, and MP11 is connected respectively with capacitors C1, C2, C3, C4 and C5 to the Vcc, while another terminal is connected respectively with the output points a, b, c, d, e of inverters 21, 22, 23, 24, 25. Thus Signals having same frequency but different phases are generated respectively at the output points a, b, c, d, e of inverters 21, 22, 23, 24, 25.

The voltage of the CC1 signal will control the width of the channel between the source and the drain of each PMOS MP7, MP8, MP9, MP10 and MP11, therefore current flowing through each of the channels is controlled and the frequency of the signals at points a, b, c, d, e can be adjusted. Since the votage of the CC1 signal is varied continuously, the frequency of the signals at points a, b, c, d, e can therefore be adjusted continuously.

The CC1 signal can be selected from outputs of the amplifier 26 or the digital-to-analog converter 28. If the output of the amplifier 26 is selected, then the voltage VM dominates. If the output of the digital-to-analog converter 28 is selected, then an external accurate digital signal DATA will dominate to adjust the frequency of the signals at points a, b, c, d, e.

Since all the gates of MP1, MP2, MP3, MP4, MP5 and MP6 are connected together, currents flowing through MP1, MP2, MP3, MP4, MP5 and MP6 are the same. This is what so called a current mirror circuit.

Please note that the voltage VM in FIG. 2 depends upon MP1 and resistor R1, since resistor R1 is fixed, currents flowing through MP1, MP2, MP3, MP4, MP5 and MP6 cannot be adjusted.

### OBJECTS OF THE INVENTION

It is therefore an object of the present invention to use MOS device to replace for example the fixed resistor in the current mirror control circuit before the voltage-controlled oscillator in a phase-locked loop circuit for controlling the current of related MOS device in the voltage-controlled oscillator of a phase-locked loop circuit, and for controlling the operating frequency of the phase-locked loop circuit.

### BRIEF DESCRIPTION OF THE DRAWINGS

FIG. 1 shows the block diagram of a conventional phase-locked loop circuit.

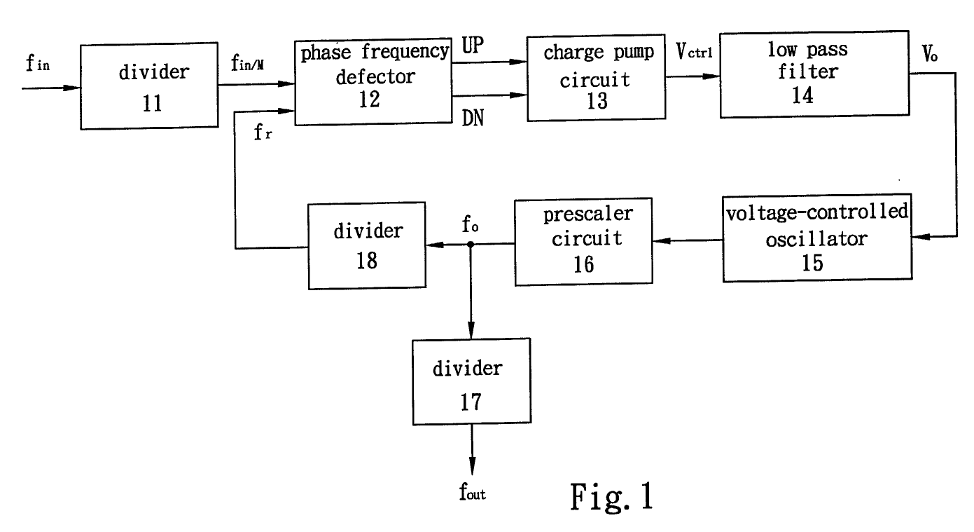

FIG. 2 shows a prior improved circuit design of the voltage-controlled oscillator in a conventional phase-locked loop circuit.

FIG. 3 shows various schematic diagrams that MOS device is used to replace the fixed resistor in the current mirror control circuit before the voltage-controlled oscillator in a phase-locked loop circuit.

### DETAILED DESCRIPTION OF THE INVENTION

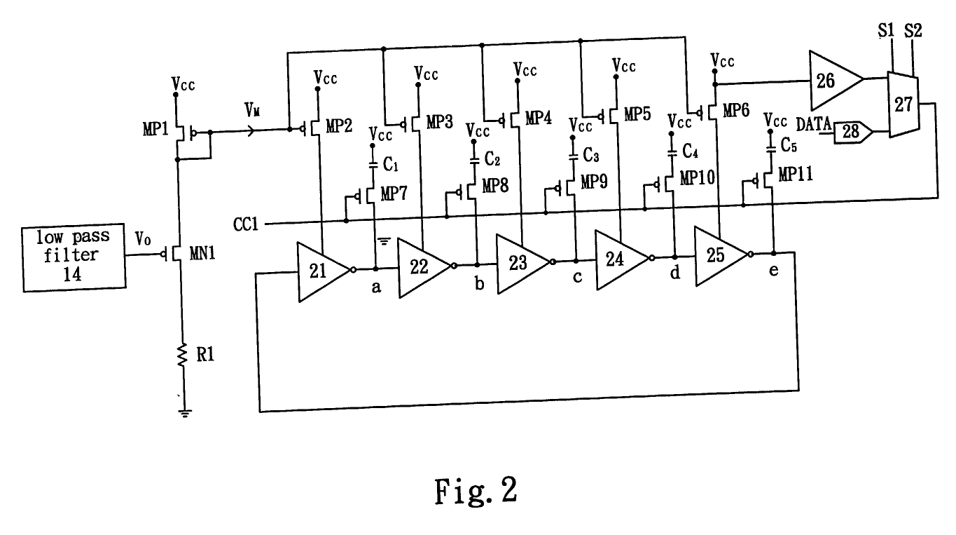

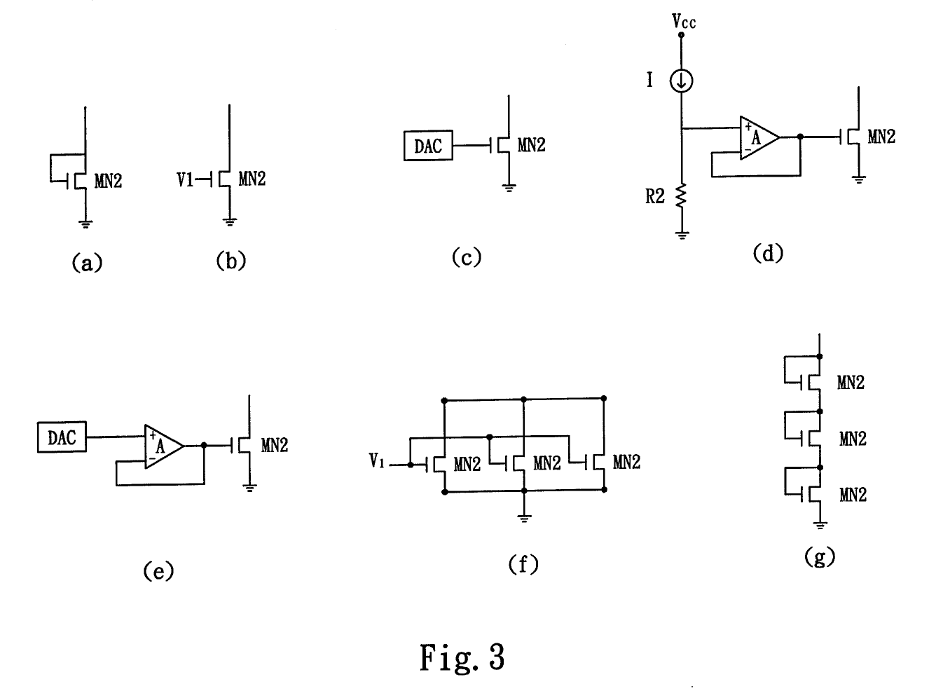

Referring to FIG. 2 and FIG. 3, the present invention of using MOS device to replace the fixed resistor in the current mirror control circuit before the voltage-controlled oscillator in a phase-locked loop circuit is described as below.

FIG. 3(a) shows an NMOS MN2, in which the source and the gate of MN2 are connected together to form a resistor that can replace the resistor R1 in FIG. 2. The advantages of using MOS device to replace the resistor R1 in FIG. 2 are that the manufacturing process can be simplified and the noise can be reduced.

FIG. 3(b) shows an NMOS MN2, the difference between FIG. 3(b) and FIG. 3(a) is that the source and the gate of MN2 in FIG. 2(b) is not connected together, and an adjustable voltage VI is inputted into the gate of MN2 to control the current in MN2. When the current in MN2 is controlled, the currents in MP1, MP2, MP3, MP4, MP5 and MP6 are actually also under control.

FIG. 3(c) shows an NMOS MN2, in which the gate of MN2 is connected with a digital-to-analog converter (DAC). The input of DAC is an accurate digital signal, while the output of DAC is an analog voltage signal, therefore the accurate digital signal can be used to control the current in MN2.

FIG. 3(d) shows an NMOS MN2, in which the gate of MN2 is connected with an operational amplifier A, and a current source I and a resistor R2 are connected at the input side of the operational amplifier A, as shown in the figure. The current of the current source I decides the input voltage of the operational amplifier A, thus the output voltage of the operational amplifier A is under control, and so does the current in MN2. The purpose of adding operational amplifier A is for isolating noise.

FIG. 3(e) shows an NMOS MN2, in which the gate of MN2 is connected with an operational amplifier A, and a digital-to-analog converter (DAC) is connected at the input side of the operational amplifier A, as shown in the figure. FIG. 3(e) is an improvement of the FIG. 3(c), and the purpose of adding operational amplifier A is also for isolating noise.

FIG. 3(f) shows three NMOS MN2 parallelly connected to replace the resistor R1 in FIG. 2, so that the frequency of the output signal in the voltage-controlled oscillator of a phase-locked loop circuit can be increased. FIG. 3(g) shows three NMOS MN2 serially connected to replace the resistor R1 in FIG. 2, so that the frequency of the output signal in the voltage-controlled oscillator of a phase-locked loop circuit can be reduced.

The scope of the present invention depends only upon the following Claims, and is not limited by the above embodiment. The current mirror circuit of the present invention is not just limited to that of the voltage-controlled oscillator of a phase-locked loop circuit.

What is claimed is:

1. A current mirror circuit, comprising a plurality of MOS devices connected parallelly to drive related circuits respectively with same current, the gates of said MOS-devices being connected together; and comprising another MOS device for triggering said same current connected parallelly with said plurality of MOS devices, a gate of said another MOS device being connected with the gates of said plurality of MOS devices, and being connected with a drain thereof, and then being connected with a source of a further MOS device for inputting signal; a gate of said further MOS device being an input terminal of said current mirror circuit, while a drain thereof being connected with a controlling MOS circuit; said controlling MOS circuit being an MOS device with a source and a gate thereof being connected to form like a resistor.

2. A current mirror circuit according to claim 1, wherein said controlling MOS circuit being an MOS device with a source and a gate thereof being not connected, and the gate being inputted with an adjustable voltage to control the current in said controlling MOS circuit.

3. A current mirror circuit according to claim 1, wherein said controlling MOS circuit being an MOS device, with a gate thereof being connected with a digital-to-analog converter (DAC), the input of said DAC being an accurate digital signal, while the output of said DAC being an analog voltage signal, therefore the accurate digital signal can be used to control the current in said controlling MOS circuit.

4. A current mirror circuit according to claim 1, wherein said controlling MOS circuit being an MOS device, with a gate thereof being connected with an operational amplifier, and a current source and a resistor being connected at the input side of said operational amplifier, the current of the current source decides the input voltage of the operational amplifier, thus the output voltage of the operational amplifier is under control, and so does the current in said controlling MOS circuit.

5. A current mirror circuit according to claim 1, wherein said controlling MOS circuit being an MOS device, with a gate thereof being connected with an operational amplifier, and a digital-to-analog converter (DAC) being connected at the input side of the operational amplifier.

6. A current mirror circuit according to claim 1, wherein said controlling MOS circuit being a plurality of MOS devices connected parallelly, with gates thereof being connected together to be inputted with an adjustable votage for controlling the current in said controlling MOS circuit.

7. A current mirror circuit according to claim 1, wherein said controlling MOS circuit being a plurality of MOS devices connected serially, with the gate and the source of each MOS device being connected to form like a resistor.
